(19) United States
(12) Patent Application Publication
(10) Pub. No.: US 2012/0242621 A1
(43) Pub. Date: Sep. 27, 2012

(54) IMAGE SENSOR AND DISPLAY DEVICE INCORPORATING THE SAME

(76) Inventors: Christopher James BROWN, Oxford (GB); Dauren ISLAMKULOV, Reading (GB)

(21) Appl. No.: 13/071,081

(22) Filed: Mar. 24, 2011

(51) Int. Cl. G06F 3/042; H01L 27/146

(52) U.S. Cl. 345/175; 250/208.1

(57) ABSTRACT

An image sensor includes an array of sensor pixel circuits, each pixel circuit comprising first and second photosensitive elements. The image sensor is configured such that a field of view of the second photosensitive element is a sub-set of a field of view of the first photosensitive element.

### TECHNICAL FIELD

The present invention relates to image sensor devices. In particular, this invention relates to image sensors integrated with liquid crystal display (LCD) devices. Such an LCD device with integrated image sensor may be used to create a display with an in-built touch panel function or may form a contact scanner capable of capturing an image of any object or document placed on the surface of the display.

### BACKGROUND ART

Display devices commonly form only one element of a user interface for electronic products. Typically, an input function or means for the user to control the device must be provided in addition to the output function provided by the display. Although historically the input function and output function have been provided by separate devices, it is desirable to integrate both functions within one device in order to reduce the total product size and cost. One well-known means of adding an input function to a display, such as an active matrix liquid crystal display (AMLCD), is to integrate an image sensor array within the display pixel matrix. For example, “Touch Panel Function Integrated LCD Using LTPS Technology” (International Display Workshops, AMD7-4L, pp. 349, 2004) describes an AMLCD with integrated image sensor which may be used for the purposes of creating a display with in-built optical-type touch panel function. Alternatively, U.S. Pat. No. 7,737,962 (Nakamura et al., Jun. 15, 2010) describes an LCD with integrated image sensor which may be used to create a contact scanner function to capture images of objects or documents placed on the surface of the display.

In devices such as these, the performance of the optical-type touch panel and contact imager functions are to a large extent dictated by the optical design of the image sensor. However, since the image sensor and display are formed by the same device, it is not possible to add optical elements, such as a lens, to the image sensor without affecting the display output image. Accordingly, with no lens to focus light onto the image sensor, light incident on the device from a wide range of angles contributes to the signal generated in each pixel of the image sensor. The result is that a high degree of blurring is evident in the sensor output image and any objects not in close proximity to the image sensor cannot be correctly imaged. This phenomenon limits the usefulness of both the touch panel and contact image functions as now described.

The problem is firstly illustrated in the graph of FIG. 1 which shows the response of a typical image sensor without a lens to incident light at different angles of incidence. The graph shows angle of incidence, φ, on the x-axis and magnitude of the image sensor output signal, I, on the y-axis. The plot is characterized by the sensor field-of-view, F(φ), which is defined by a set of angles that correspond to a generated output signal level greater than a certain value, for example greater than 50% of the maximum generated signal. FIG. 2 shows the same problem but illustrated by a 2-dimensional contour plot. The contour plot is characterized by the sensor field-of-view in two dimensions, F(φ,Ψ), which is shown as a contour on the surface plot. To close approximation, light incident on the display surface inside the range of angles defined by the field-of-view is detected by the sensor and light incident on the display surface outside this field-of-view is not detected by the sensor.

As a result of the wide field-of-view of each pixel in the sensor, the performance of both the optical touch panel and contact scanner functions is limited. In the case of the optical touch panel, it is the robustness to changing ambient lighting conditions that is affected by the wide field-of-view. For example, an object touching the display surface will reflect light from the display backlight back towards the image sensor whilst blocking ambient light. However, when the sensor pixel has a wide field-of-view, the object touching the display surface may not completely block all of the incident ambient light and the pixel may generate a large spurious signal. This large signal is a source of error since it reduces the contrast of the sensor output image and makes reliable detection of touch events difficult.

In the case of the contact scanner, the spatial resolution of the captured image of the object or document on display surface is relatively low. The maximum spatial resolution which can be detected is determined by the area on the surface of the object or document from which a single image sensor pixel can collect light reflected by the object or document from the display backlight. This area is defined both by the distance from the object or document to the image sensor, and by the field-of-view of the image sensor. Thus, an image sensor with a wide field-of-view will create a contact scanner with a relatively low spatial resolution.

From the above explanation it is clearly desirable to create an image sensor structure with a narrow field-of-view without the addition of bulk optics elements such as lenses. One method of reducing the field-of-view is disclosed in WO2010/097984 (Katoh et al., Feb. 27, 2009). This method is successful in reducing the field-of-view to some extent, as shown in FIG. 3A, although it remains relatively wide and the problems of ambient light in the touch panel function and low spatial resolution in the contact imager function are not adequately resolved. An improved method to reduce the field-of-view is disclosed in GB0909425.5 (Castagner et al., Jun. 2, 2009). In this method, the field-of-view is now adequately reduced in the first elevation dimension, as shown in FIG. 3B, but the field-of-view in the second azimuthal dimension remains relatively wide and the problems described above still remain. A solution to reduce the field-of-view in two dimensions is therefore sought.

### SUMMARY OF INVENTION

In accordance with the present invention, an image sensor with narrow field-of-view may be formed by an array of sensor pixel circuits in which each pixel circuit comprises a pair of two separate photosensitive elements and the sensor pixel output is proportional to the difference in the signals generated by the two photosensitive elements. Within each pixel, the field-of-view of one photosensitive element is arranged to be a sub-set of the field-of-view of the other photosensitive element such that the resultant output signal from the sensor pixel circuit is equivalent to a sensor with a narrow field-of-view.

In order to create the desired field-of-view associated with each photosensitive element, a light blocking layer is provided between each element and the illumination source. Apertures are formed in this light blocking layer to allow only light incident on the sensor within a fixed range of angles to strike each element. A first aperture is associated with the first photosensitive element to define a first field-of-view and a second aperture is associated with the second photosensitive element to define a second field-of-view. As described above, the effective field-of-view for the pixel is the difference between the fields-of-view of these two elements and may therefore be much narrower than either element's field-of-view alone.

In this way, an image sensor with a narrow field-of-view is created without the use of lens or other bulk optics elements. Such an image sensor may be integrated within an active matrix liquid crystal display (AMLCD) to form an optical-type touch panel function which is insensitive to ambient lighting conditions or a contact image scanner function capable of capturing high-resolution images.

According to one aspect of the invention, an image sensor includes an array of sensor pixel circuits, each pixel circuit comprising first and second photosensitive elements, wherein a field of view of the second photosensitive element is a sub-set of a field of view of the first photosensitive element.

According to one aspect of the invention, the image sensor includes a circuit configured to measure a difference in signals generated by the first and second photosensitive elements so as to create an effective field-of-view for the image sensor that is the difference between the fields-of-view of the first and second photosensitive elements.

According to one aspect of the invention, the image sensor includes a light-blocking layer arranged relative to the first and second photosensitive elements; and a first and a second aperture formed in the light-blocking layer, the first aperture corresponding to the first photosensitive element and the second aperture corresponding to the second photosensitive element, the first and second apertures arranged relative to the first and second photosensitive elements, respectively, to create substantially the same field of view in each photosensitive element in a first angular dimension, and different fields-of-view in a second angular dimension.

According to one aspect of the invention, a location of the first aperture is characterized in an x-direction by an offset between an edge of the first photosensitive element adjacent to the first aperture and a width of the first aperture, and characterized in the y-direction by a length of the first aperture being substantially the same as a length of the photosensitive element in the y-direction.

According to one aspect of the invention, a location of the second aperture is characterized in the x-direction by an offset between an edge of the second photosensitive element adjacent to the second aperture and width of the second aperture, and characteristics of the second aperture in the x-direction are substantially the same as the characteristics of the first aperture in the x-direction.

According to one aspect of the invention, the second aperture is split into two sub-apertures formed on either side of the second photosensitive element, and each sub-aperture is characterized in the y-direction by an offset from the edge of the second photosensitive element adjacent to the sub-apertures and a length of the sub-apertures.

According to one aspect of the invention, the length and offset of the sub-apertures in the y-direction are chosen such that two distinct fields-of-view in the second angular dimension are created, each distinct field-of-view being a sub-set of the field-of-view of a one dimensional field-of-view in azimuth created by the first aperture.

According to one aspect of the invention, the first and second photosensitive elements comprise thin-film lateral p-i-n type photodiodes.

According to one aspect of the invention, the image sensor further includes an imaging surface for placing an object to be imaged, wherein the first and second apertures are arranged relative to the first and second photosensitive elements, respectively, such that fields-of-view in elevation for the first and second photosensitive elements overlap in the x-axis direction at the imaging surface.

According to one aspect of the invention, the first photosensitive element and the second photosensitive element are formed by a plurality of separate photosensitive sub-elements arranged in parallel.

According to one aspect of the invention, the image sensor further includes a second light blocking layer, wherein the first and second photosensitive elements comprise a thin-film lateral photodiode including a control electrode formed by the second light blocking layer.

According to one aspect of the invention, the thin-film photodiodes comprise a silicon layer, and the second light blocking layer is disposed beneath the silicon layer.

According to one aspect of the invention, the control electrode of the first and second photodiodes is configured to control a photo-generation profile of the respective photodiode.

According to one aspect of the invention, the first and second apertures are arranged adjacent to a cathode terminal of the first and second photodiodes, respectively.

According to one aspect of the invention, the image sensor further includes a first control electrode address line configured to supply voltage to the control electrode of the first photosensitive element, and a second control electrode address line configured to supply voltage to the control electrode of the second photosensitive element.

According to one aspect of the invention, image sensor circuit elements are formed by an active pixel sensor circuit.

According to one aspect of the invention, the active pixel sensor circuit includes an amplifier configured to amplify a signal generated by the photosensitive elements.

According to one aspect of the invention, the image sensor further includes a display pixel circuit, wherein the image sensor is integrated together with the display pixel circuit to from a combined pixel circuit configured to perform both output display and input sensor functions.

According to one aspect of the invention, the combined display and sensor pixel circuit is formed by distribution of image sensor circuit elements across a plurality of display pixel circuits.

According to one aspect of the invention, the first and second photosensitive elements are electrically connected to each other to form a summing node, further comprising a switching device electrically coupled to the summing node.

According to one aspect of the invention, a contact scanner includes the image sensor described herein.

According to one aspect of the invention, a touch panel includes the image sensor described herein.

According to one aspect of the invention, a method of generating a narrow-field of view for an image sensor integrated with an LCD device, said image sensor including first and second photosensitive elements includes: configuring a field of view of the second photosensitive element to be a sub-set of a field of view of the first photosensitive element; generating an effective field of view for the image sensor from a difference between a signal generated by the first photosensitive element and a signal generated by the second photosensitive element.

According to one aspect of the invention, configuring includes providing the first and second photosensitive elements with substantially the same field of view in a first angular dimension, and different fields-of-view in a second angular dimension.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

FIG. 1 shows a graph of the field-of-view of a lens-less image sensor in one-dimension

FIG. 2 shows a surface contour plot of the field-of-view of a lens-less image sensor

FIG. 3 shows improvements to the field of view: FIG. 3A shows result of arrangement disclosed in [08J04392]; FIG. 3B shows result of arrangement disclosed in GB0909425.5.

FIG. 4 shows a block diagram of display device with integrated image sensor

FIG. 5 shows a schematic diagram of a basic concept of the invention: two photosensitive elements arranged with apertures to reduce the sensor field-of-view

FIG. 6 shows the relationship between the construction of the photosensitive elements and the associated field-of-view: FIG. 6A shows a cross-section of the photosensitive elements; FIG. 6B shows a plan view of the photosensitive elements.

FIG. 7 shows the one-dimensional field-of-view associated with a first embodiment of this invention: FIG. 7A shows the field-of-view in elevation associated with the first photosensitive element; FIG. 7B shows the field-of-view in elevation associated with the second photosensitive element; FIG. 7C shows the field-of-view in azimuth associated with the first photosensitive element; FIG. 7D shows the field-of-view in azimuth associated with the second photosensitive element.

FIG. 8 shows the surface contour plot of the field-of-view associated with the first embodiment of this invention

FIG. 9 shows a waveform diagram illustrating the operation of the first embodiment of this invention

FIG. 10 shows a schematic diagram of the combined display and sensor pixel circuit of the first embodiment of this invention

FIG. 11 shows the construction of the display and sensor device of the first embodiment of this invention

FIG. 12 shows the relationship between the construction of the photodiodes of a second embodiment of this invention and the associated field-of-view

FIG. 13 shows the photo-generation profile of the photodiodes of the second embodiment of this invention

FIG. 14 shows a schematic diagram of the sensor pixel circuit of a third second embodiment of this invention

FIG. 15 shows the one-dimensional field-of-view associated with the third embodiment of this invention: FIG. 14A shows the field-of-view in elevation associated with the first photosensitive element; FIG. 14B shows the field-of-view in elevation associated with the second photosensitive element.

FIG. 16 shows the relationship between the construction of the photosensitive elements and the associated field-of-view of the third embodiment of this invention: FIG. 15A shows a cross-section of the photosensitive elements; FIG. 15B shows a plan view of the photosensitive elements.

FIG. 17 shows the relationship between the layout of the photosensitive elements and the associated field-of-view of a fourth embodiment of this invention

FIG. 18 shows the construction of the photodiode devices of a fifth embodiment of this invention

FIG. 19 shows the relationship between the voltage applied to the terminals of the photodiode devices of a sixth embodiment and the photo-generation profile

FIG. 20 shows the relationship between the construction of the photodiodes of the sixth embodiment of this invention and the associated field-of-view

FIG. 21 shows a schematic diagram of the sixth embodiment of this invention

FIG. 22 shows a schematic diagram of a seventh embodiment of this invention

FIG. 23 shows a waveform diagram illustrating the operation of the seventh embodiment of this invention

FIG. 24 shows a schematic diagram of an eighth embodiment of this invention

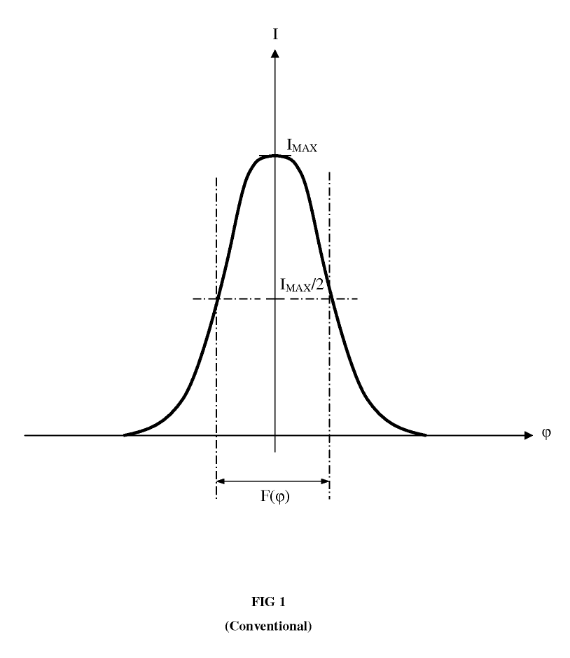

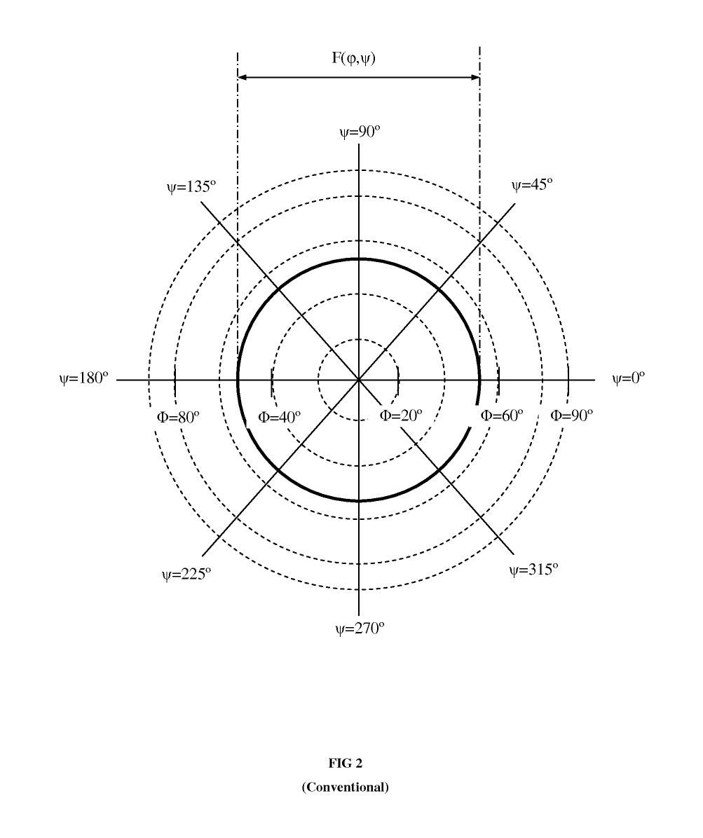

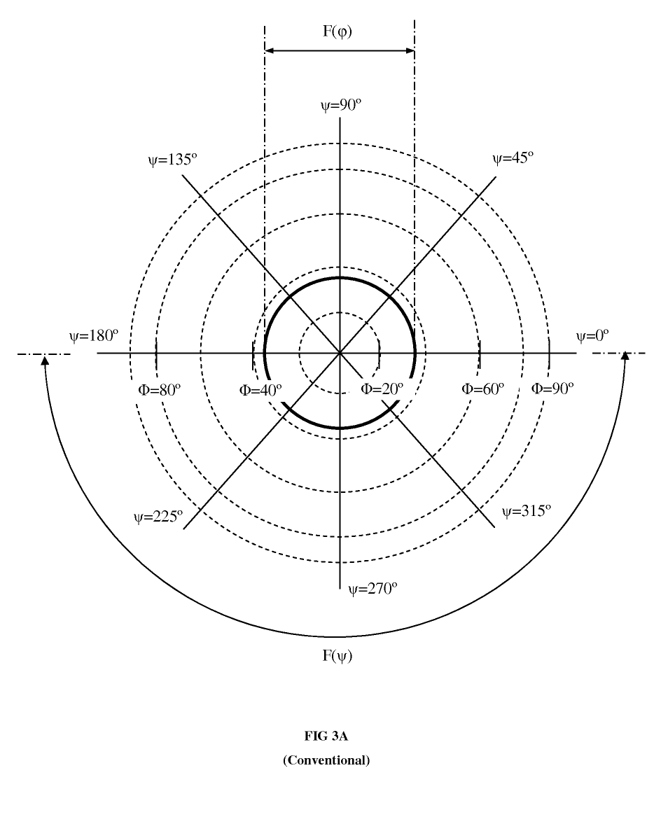

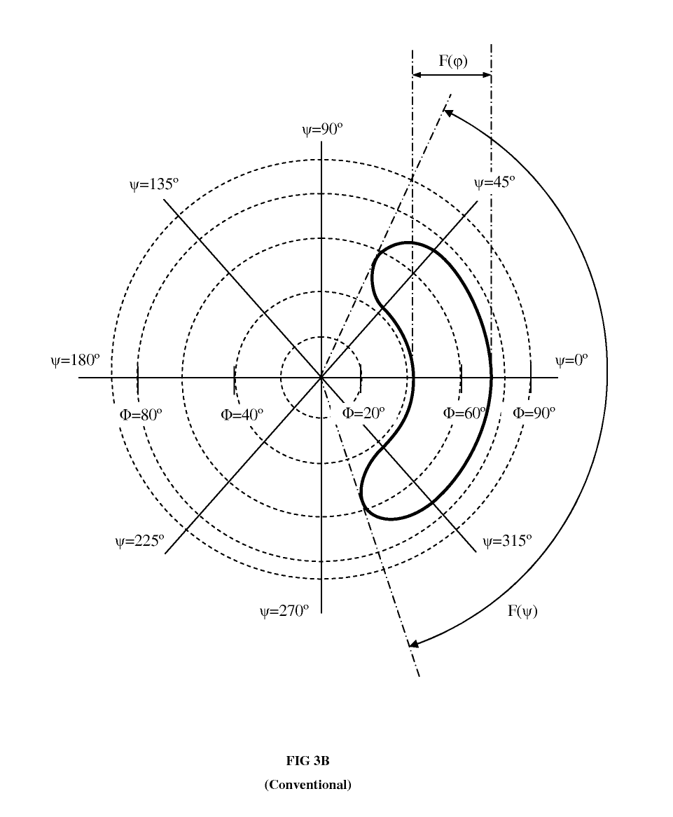

### DESCRIPTION OF REFERENCE NUMERALS

100 Image sensor circuit elements
101 First photosensitive element
102 Second photosensitive element
103 Light blocking layer
104 First aperture
105 Second aperture
106 Switch transistor
108 First power supply line
109 Second power supply line
110 Pixel row select signal line
120 Display circuit elements
121 Combined display and sensor pixel circuit
122 Sensor pixel circuit
123 Display pixel circuit
130 Pixel matrix
131 Pixel output signal line
140 Thin-film transistor substrate
141 First electronics layer
150 Display driver circuit
160 Sensor driver circuit
161 Sensor read-out circuit
162 Sensor data processing unit
163 Pixel sampling circuit
164 Analog-to-digital conversion circuit
165 Operational amplifier
166 Integration capacitor
167 Integrator reset switch transistor
170 Counter substrate
171 Second electronics layer
172 Liquid crystal material
173 First (TFT substrate) polarizer
174 Second (counter substrate) polarizer
175 Backlight unit
176 Optical compensation films
177 Transparent protective substrate
178 Air-gap
180 Ambient illumination
181 Environmental sources of illumination
182 Reflected light
183 Objects touching display
201 First photodiode
202 Second photodiode
203 n+ doped region of photodiode
204 p+ doped region of photodiode
205 intrinsic region of photodiode
206 Depletion region
210 Base-coat
211 Second (lower) light blocking layer
220 First photosensitive sub-element forming first photosensitive element
221 Second photosensitive sub-element forming first photosensitive element
230 Third photosensitive sub-element forming second photosensitive element
231 Fourth photosensitive sub-element forming second photosensitive element
240 First control electrode
241 Second control electrode
242 First control electrode address line
243 Second control electrode address line
300 Active pixel sensor circuit
301 Integration capacitor
302 Pixel amplifier transistor
303 Pixel reset transistor
304 Pixel row select transistor
310 Pixel reset signal input address line
311 Pixel row select input signal address line
312 Pixel first power supply line
314 Pixel second power supply line
320 Column address line
400 Display pixel switch transistor
401 Display pixel storage capacitor
402 Liquid crystal element
403 Gate address line (GL)
404 Source address line (SL)
405 Display first common electrode (TFTCOM)
406 Display second common electrode (VCOM)

### DETAILED DESCRIPTION OF INVENTION

A device and method in accordance with the present invention provides a means of creating an image sensor with narrow field-of-view without the use of a lens or other bulk optics structure. The improved optical performance provided by the device and method in accordance with the invention enables both a touch panel with more reliable operation and a contact scanner capable of capturing images of a higher spatial resolution than would otherwise be possible.

In one embodiment, an image sensor in accordance with the present invention includes an array of sensor pixel circuits, each pixel circuit having first and second photosensitive elements, wherein a field of view of the second photosensitive element is a sub-set of the field of view of the first photosensitive element. The sensor pixel circuit is arranged to subtract the signal generated by the second photosensitive element from the signal generated by the first photosensitive element such that the effective field of view corresponding to the sensor pixel output signal is narrow.

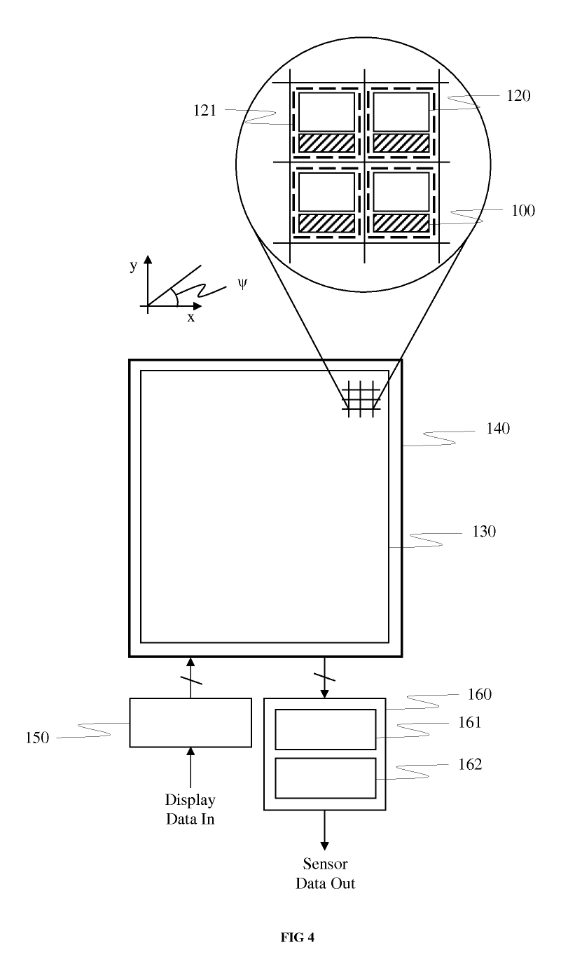

An exemplary device in accordance with the invention, shown in FIG. 4, contains image sensor circuit elements 100 which are integrated alongside display pixel circuit elements 120 in each pixel 121 of a plurality of pixels forming the pixel matrix 130 of the AMLCD. The image sensor pixel circuit elements 100 are formed on the thin-film transistor (TFT) substrate 140 of the AMLCD using the same thin-film processing techniques used in the manufacture of the display circuit elements 120. The operation of the display pixel circuit elements 120 is controlled by a display driver circuit 150 which may be separate from or combined with a sensor driver circuit 160 which controls the operation of the image sensor pixel circuit elements 100. The sensor driver circuit 160 includes a read-out circuit 161 to sample the signals generated by the image sensor pixel circuit elements 100 and a processing unit 162 to analyse the output signals.

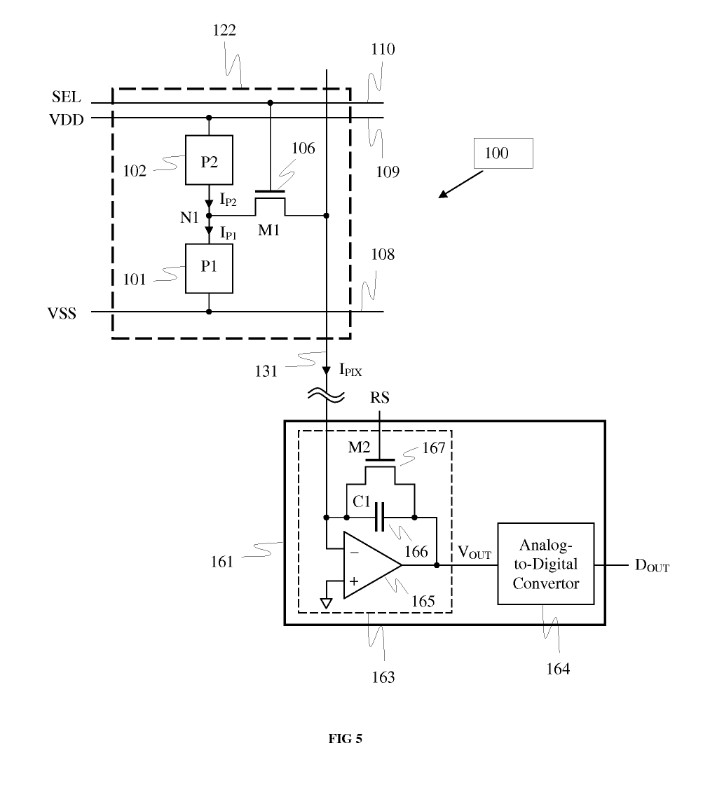

FIG. 5 shows a schematic diagram of the image sensor circuit elements 100 according to a first and most basic embodiment of this invention. The image sensor circuit elements 100 are arranged to form a sensor pixel circuit 122 which may comprise a first photosensitive element (P1) 101 and a second photosensitive element (P2) 102. The photosensitive elements may be formed by devices that are compatible with thin-film processing techniques used in the manufacture of an AMLCD such as photo-resistors, photo-diodes or photo-transistors. The circuit elements 100 may further comprise a switch transistor 106, a low potential power supply line (VSS) 108, a high potential power supply line (VDD) 109 and a row select input signal line (SEL) 110. The low potential power supply line 108 and the high potential power supply line 109 may be common to all sensor pixel circuits 122 in one row of the pixel matrix 130. An output signal line (OUT) 131 is used to connect the output terminal of the switch transistor 106 to the input of the read-out circuit 161 and may be common to all image sensor circuit elements 100 in one column of the pixel matrix 130. The read-out circuit 161 may further comprise a current-to-voltage conversion circuit 163 and an analog-to-digital convertor circuit 164. The current-to-voltage conversion circuit 163 may itself be of a well-known type, for example an integrator circuit, and formed by standard components such as an operational amplifier 165, an integration capacitor (C1) 166 and a reset switch transistor (M2) 167 controlled by an integrator reset signal (RS). Many other read-out circuits capable of performing this current-to-voltage conversion are well-known and may equally be used in place of the circuits described above. The analog-to-digital conversion circuit 164 may be of any suitable well-known type and is not described further herein.

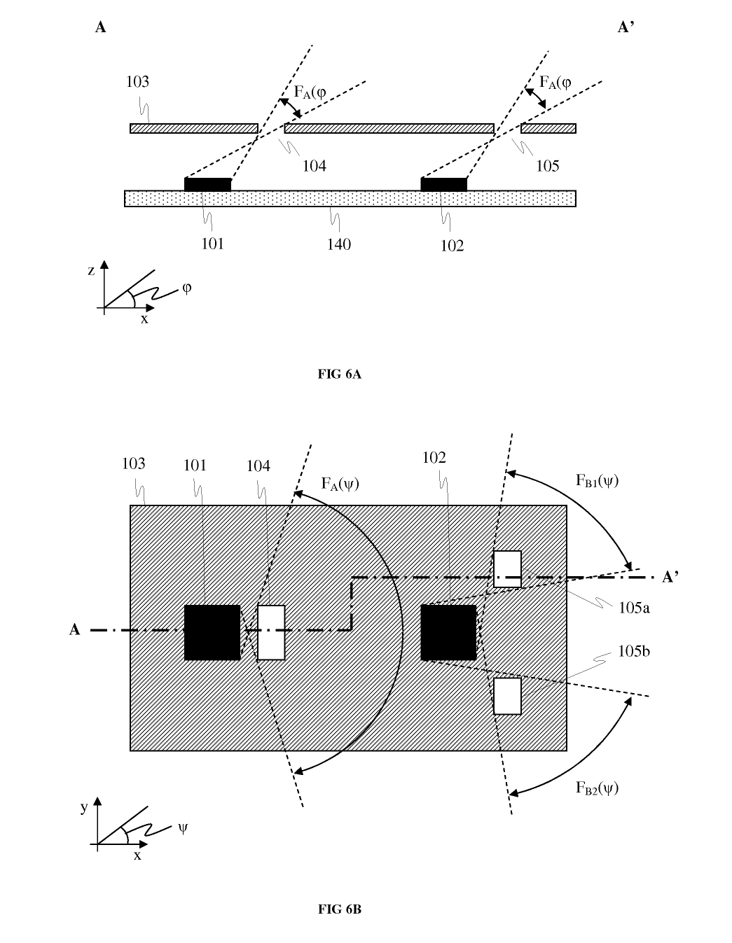

As shown in the cross-section diagram of FIG. 6A, a light blocking layer 103 is arranged relative to (e.g., above) the photosensitive elements of the pixel circuit to prevent illumination incident on the surface of the display from striking the photosensitive element. The light blocking layer 103 may be made from any material which is non-transparent, such as a metallization layer used in standard LCD fabrication techniques. In the case that the light blocking layer is formed by an electrically conductive material, the layer may be either electrically connected to a fixed potential, such as the ground potential. Apertures are formed in the light blocking layer wherein a first aperture 104 is associated with the first photosensitive element 101 and a second aperture 105 is associated with the second photosensitive element 102. The apertures define a range of angles of incidence within which the illumination incident on the surface of the device may pass the light blocking layer and strike the photosensitive elements. Illumination incident on the surface of the device outside the range of angles of incidence defined by an aperture is prevented from striking the associated photosensitive element by the light blocking layer 103. The range of angles of incidence defined by the aperture is known as the field-of-view of the photosensitive element.

The first aperture associated with the first photosensitive element and the second aperture associated with second photosensitive element are arranged to create substantially the same field-of-view in each photosensitive element in a first angular dimension (a field-of-view is considered “substantially the same” when the differences in the angle of maximum response (φ_{A,MAX, B,MAX}) and full-width half maximum angle (F_{A}(φ), F_{B}(φ)) are no greater than 10%) but different fields-of-view in the second angular dimension. A plan diagram of an aperture arrangement to achieve this desired characteristic is shown in FIG. 6B. A location of the first aperture is characterized in the x-direction by an offset between an edge of the first photosensitive element that is adjacent to the first aperture and a width of the first aperture. Preferably, the offset is between zero and a width of the photosensitive element. The first aperture is further characterized in the y-direction by an aperture length which is chosen to be to be substantially the same as a length of the photosensitive element in the y-direction (aperture lengths are considered “substantially the same” when the difference in the lengths is no greater than 10%). The second aperture is characterized in the x-direction by an offset between an edge of the second photosensitive element adjacent to the second aperture and a width of the second aperture. A preferred range of the offset is between zero and a width of the photosensitive element. In order to create substantially the same field-of-view in one angular dimension, the characteristics of the second aperture in the x-direction are substantially the same as the characteristics of the first aperture in the x-direction (characteristics of the aperture are considered “substantially the same” when. the dimensions of the first and second aperture differ by no more than 10%). The second aperture is split into two sub-apertures 105a and 105b formed on either side of the second photosensitive element wherein each sub-aperture is characterized in the y-direction by an offset from the edge of the photosensitive element adjacent to the sub-apertures and length of the sub-apertures. Preferably, the offset is between zero and a length of the photosensitive element.

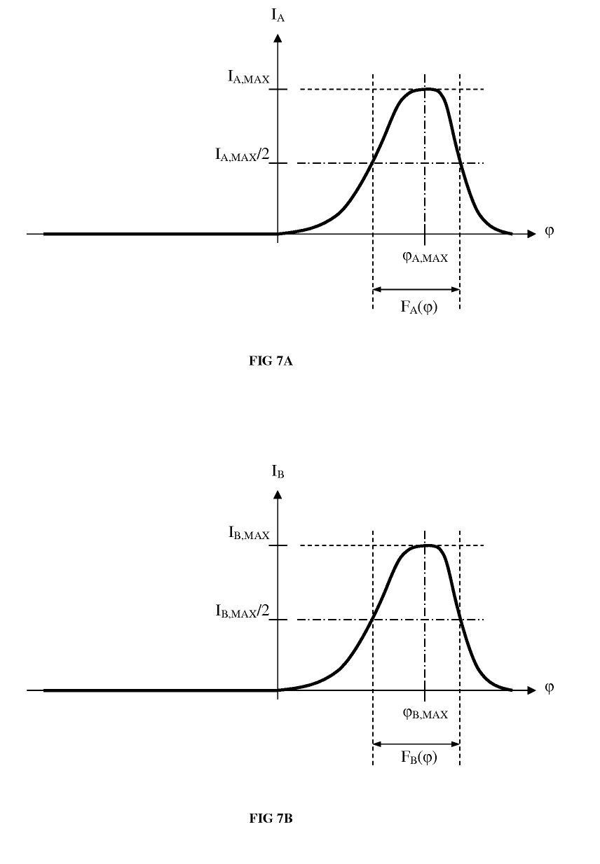

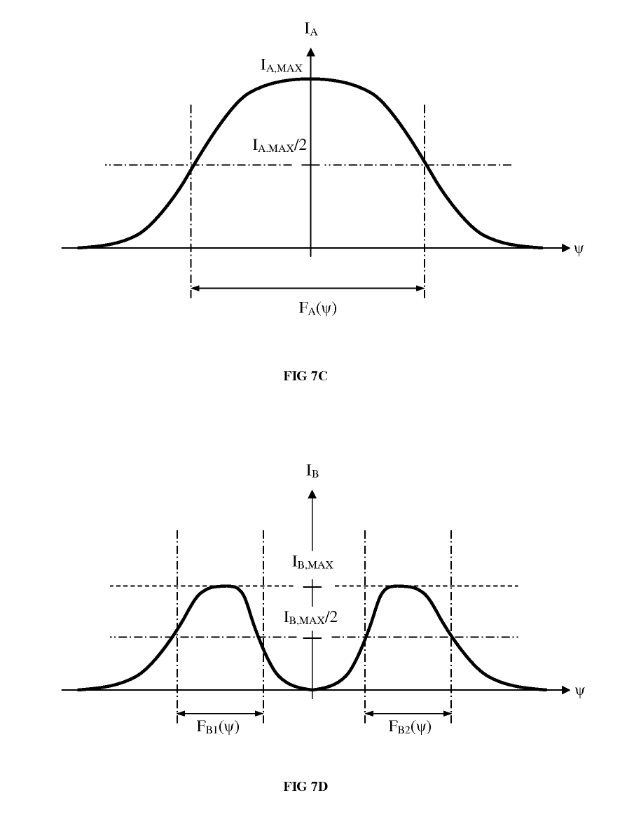

In the aperture arrangement described above, since the x-direction characteristics of the first and second aperture are substantially the same, the one dimensional fields-of-view in elevation, F_{A}(φ) and F_{B}(φ), are substantially the same for both photosensitive elements—shown in FIG. 7A and FIG. 7B. However, due to the difference in y-direction characteristics between the first and second aperture, the one dimensional fields-of-view in azimuth, F_{A}(Ψ) and F_{B}(Ψ), are different—shown in FIG. 7C and FIG. 7D. In particular, the length and offset of the sub-apertures of the second aperture in the y-direction are chosen such that two distinct fields-of-view in the second angular dimension, F_{B1}(Ψ) and F_{B2}(Ψ), are created and that each distinct field-of-view is a sub-set of the field-of-view of the one dimensional field-of-view in azimuth created by the first aperture, F_{A}(Ψ). Since the sensor pixel circuit is arranged to measure the difference in the signals generated by the first and second photosensitive elements, the effective field-of-view for the pixel circuit is the difference between the fields-of-view of the first and second photosensitive element. FIG. 8 shows a two-dimensional contour plot of this effective field-of-view for the pixel circuit and illustrates how a narrow field-of-view is obtained.

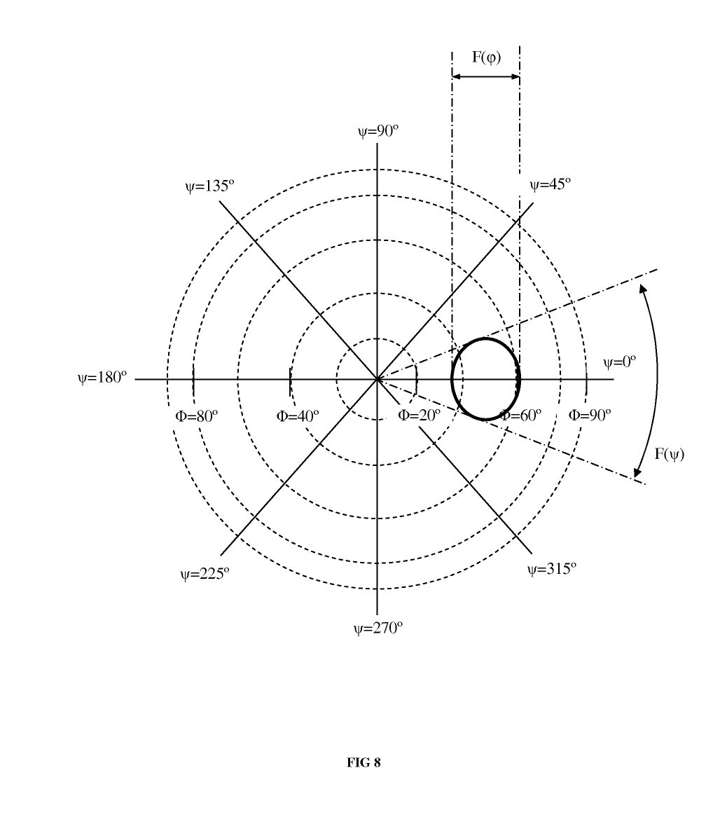

An example of the operation of the sensor pixel circuit 122 is now described with reference to the schematic diagram of FIG. 5 and the waveform diagram of FIG. 9. In a first reset period of the operation cycle the current integrator circuit forming the current-to-voltage conversion circuit 163 is reset by temporarily pulsing the reset input signal RS. This causes the integrator reset switch 167 to turn on and forces the integrator output voltage, V_{OUT}, to be equal to the voltage applied to the positive terminal of the operational amplifier 165, for example ground potential. In a second read-out period of the operation cycle the signal generated by the sensor pixel circuit 122 is sampled. The sampling operation is initiated when the pixel circuit row select line (SEL) 110 is made high and the switch transistor 106 is turned on. The summing node, N1, connecting the first photosensitive element 101 and the second photosensitive element 102 is now connected to the pixel output signal line 131 and the current flowing through the switch transistor 106, I_{PIX}, is integrated by the integrator circuit onto the integration capacitor (C1) 166. At the end of the read-out period the row select line (SEL) 110 is returned to a low potential and the pixel switch transistor 106 is turned off. The integrator output voltage, V_{OUT}, generated during the read-out period is proportional to the pixel output current, I_{PIX}, and hence to the difference in photocurrent generated by the two photosensitive elements. Finally, an analog-to-digital conversion circuit 164 may be used to convert the output voltage of the integrator circuit, V_{OUT}, into a digital signal, D_{OUT}. After the analog-to-digital conversion process has been completed, the integrator reset signal (RS) may then be made high again thus resetting the integrator and allowing the measurement cycle to be repeated indefinitely.

As described above, the pixel matrix 130 may contain a plurality of sensor pixel circuits 122 arranged in rows and columns. The read-out circuit 161 may include a plurality of sampling circuits 163 such that when the row select signal 110 is made high the output of all of the pixel circuits in one row may be sampled simultaneously. Each row select line 110 in the pixel matrix 130 is activated in turn such that the output of each pixel circuit 122 in the pixel matrix 130 is sampled and converted to a digital signal during one frame of operation.

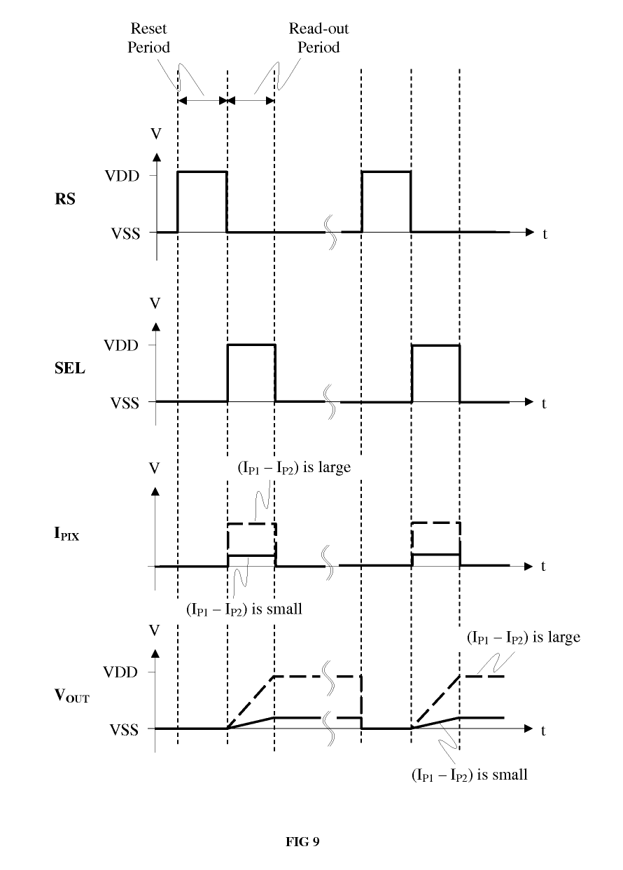

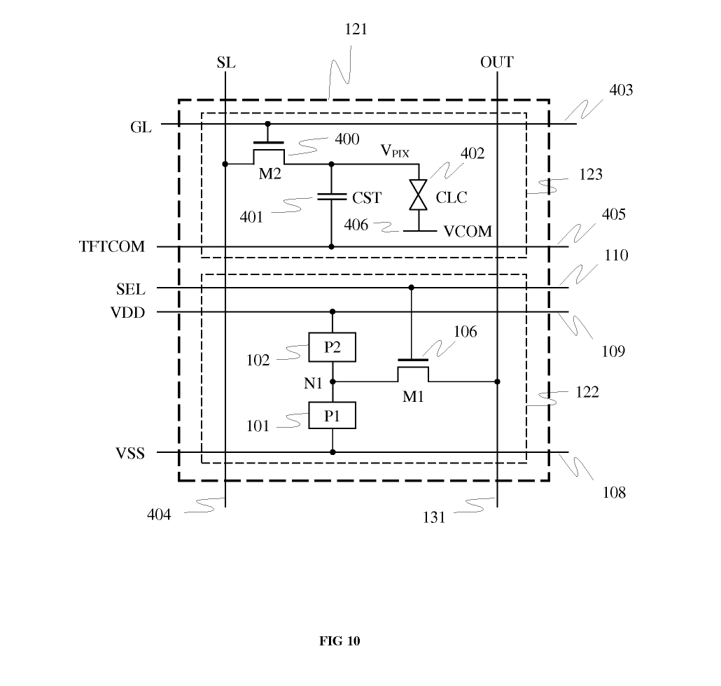

The sensor pixel circuit 122 may be integrated together with a display pixel circuit 123 formed by display circuit elements 120 to from a combined pixel circuit 121 capable of performing both output display and input sensor functions. The schematic diagram of one possible implementation of a combined pixel circuit 121 is shown in FIG. 10. Each combined sensor pixel circuit 121 comprises the sensor pixel circuit 122 described above and a display pixel circuit 123 formed from the display circuit elements 120. The display pixel circuit 123 is constructed in an arrangement that is well-known for AMLCD devices and, for example, may further comprise a switch transistor 400, a storage capacitor 401 and a liquid crystal element 402. In this arrangement, the drain terminal of the switch transistor 400 is connected to the pixel electrode, V_{PIX}, which is also connected to a first terminal of the storage capacitor 401 and a first terminal of the liquid crystal element 402. To control the display operation, the display pixel circuit also comprises a gate address line (GL) 403 common to all pixels in one row of the pixel matrix 130 and a source address line (SL) 404 common to all pixels in one column of the pixel matrix 130. The second terminal of the storage capacitor is connected to a first common electrode (TFTCOM) 405 and the second terminal of the liquid crystal element is connected to a second common electrode (VCOM) 406. The operation of the display pixel circuit 123 as described above is well-known in the field of liquid crystal displays.

FIG. 11 shows the construction of a display device with integrated image sensor in which the display circuit elements 120 and sensor circuit elements 100 together form an electronics layer 141 on the top of the TFT substrate 140. A second electronics layer 171 is integrated onto a counter substrate 170 which is arranged in opposition to the TFT substrate 140. Liquid crystal material 172 is injected into the centre of this sandwich structure and forms the optically active element of the display. As in a standard LCD construction, a first polariser 173 is added to the bottom of the TFT substrate 140 and a second polariser 174 to the top of the counter substrate 170. To complete the display module, a backlight unit 175 and optical compensation films 176 are added beneath the display and a transparent protective substrate 177 may be added above the display with or without an air-gap 178 to the second polariser 174.

Light incident on the sensor is generated either by ambient illumination 180 from environmental sources 181 or by reflected light 182 from the display backlight 175. As described previously, the image sensor pixel circuits 122 detect the amount of light incident on each pixel in the matrix and generate an electronic signal in each pixel proportional to this amount. These pixel signals are sampled by the read-out circuit 161 and combined in the processing unit 162 to form a sensor output image which represents the intensity of light incident on electronics layer 141 across the pixel matrix 131. In the case of the touch panel function, objects 183 touching the display surface are recognized by the processing unit 162 due to either a reduction in light intensity relative to the background level caused by the objects 183 obscuring ambient illumination 180 or an increase of light intensity due to reflected light 182 from the display backlight 175 by objects 183. In the case of the contact image scanner function, a document 184 to be scanned is placed on the surface of the display. The image sensor measures the intensity of reflected light 182 from the display backlight 175 by the document 184 and a digital representation of the image on the surface of the document in contract with the surface of the device is calculated by the processing unit 162.

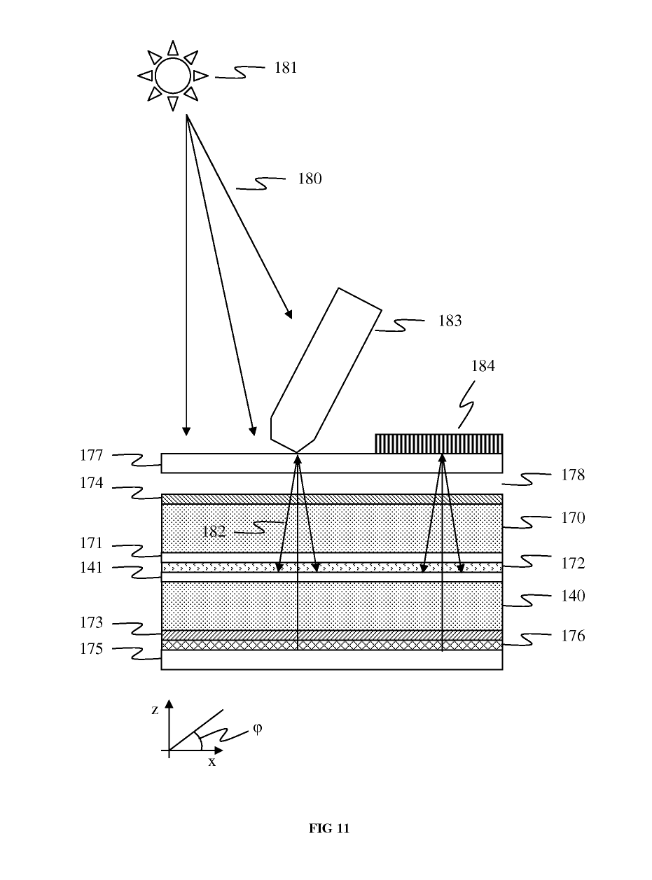

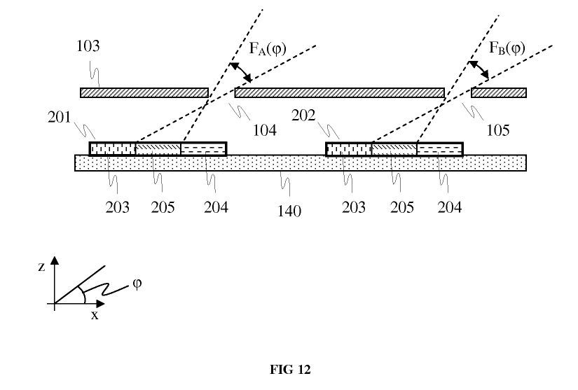

In a second embodiment of in accordance with the present invention, the photosensitive elements of this first embodiment are formed by thin-film lateral p-i-n type photodiodes wherein a first photodiode 201 constitutes the first photosensitive element 101 and a second photodiode 202 constitutes the second photosensitive element 102. The construction of thin-film lateral p-i-n type photodiodes is well-known, for example as disclosed in “A Continuous-Grain Silicon System LCD With Optical Input Function” (Journal of Solid State Circuits, Vol 42, Issue 12, pp. 2904, 2007). As shown in FIG. 12, the photodiode structure includes a heavily doped n-type semiconductor region 203 which forms the cathode terminal of the device and a heavily doped p-type semiconductor region 204 which forms the anode terminal of the device. An intrinsic or very lightly doped semiconductor region 205 is disposed between the n-type region 203 and p-type region 204. A feature of lateral p-i-n photodiodes is that the photosensitive area is substantially formed by the central intrinsic region 205 such that light falling on the device outside of this region does not substantially contribute to the photocurrent generated in the device. Accordingly, it is the intrinsic region of the photodiode that is located relative to the aperture in order to define the field-of-view of the photodiode. Thus, similar to the arrangement of the first embodiment described above, the first aperture 104 is associated with the first photodiode 201 and the second aperture 105 is associated with the second photodiode 202 such that the field-of-view of each photodiode is similar in one angular dimension but different in a second angular dimension.

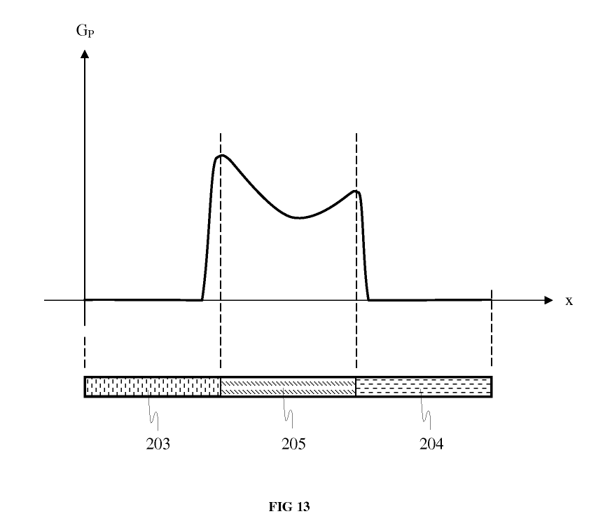

Another feature of thin-film lateral photodiodes is that the photo-generation rate, G_{P},—i.e., the number of charge carriers generated at the device output terminals per incident photon—is not uniform across the intrinsic region 205. The variation of the photo-generation rate across the intrinsic region is defined by a photo-generation profile, an example of which is shown in FIG. 13. The photo-generation rate, G_{P}, typically varies with distance from both the n-type region 203 and p-type region 204 and is substantially constant for a given distance. Since the field-of-view is a function not only of the geometry and location of the aperture with relation to the intrinsic region but also of this photo-generation profile, the n-type region and p-type regions of the first and second photodiodes are arranged in a similar orientation and location relative to the apertures. Thus, in this embodiment, the p-type region 204 of the first photodiode 201 is adjacent to the first aperture 104 and the p-type region 204 of the second photodiode 202 is adjacent to the second aperture 105.

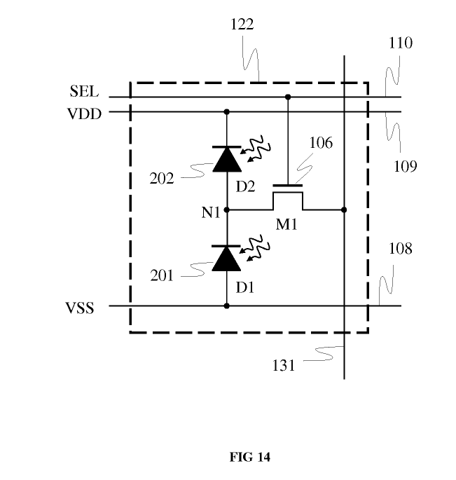

The photodiodes are arranged to form the sensor pixel circuit 122 shown in FIG. 14 which comprises: the first photodiode (D1) 201; the second photodiode (D2) 202; a switch transistor 106; a low potential power supply line (VSS) 108, a high potential power supply line (VDD) 109 and a row select input signal line (SEL) 110. The anode of the first photodiode 201 is connected to the low power supply line 108 and the cathode to a summing node N1. The anode of the second photodiode 202 is connected to the summing node N1 and the cathode is connected to the high power supply 109. The switch transistor 106 connects the summing node N1 to an output signal line (OUT) 131 such that the current flowing through the transistor when it is turned on is equal to the difference in the current flowing through the two photodiodes. The operation of this circuit is similar to that of the first embodiment as described above.

A disadvantage of the arrangement of apertures and photosensitive elements described above when used to provide a contact image scanner function is that the photosensitive elements are spatially separated. Accordingly, when a document to be scanned is placed on the surface of the display, the reflected light detected by the first photosensitive element 101 originates from a different x-axis location than the reflected light detected by the second photosensitive element 102. The result of the spatial separation of the photosensitive elements is therefore imperfect subtraction of the fields-of-view of the two elements and an unwanted decrease in the effective resolution in the sensor output image. It is therefore desirable to locate the photosensitive elements of each sensor pixel circuit 122 as close together as possible.

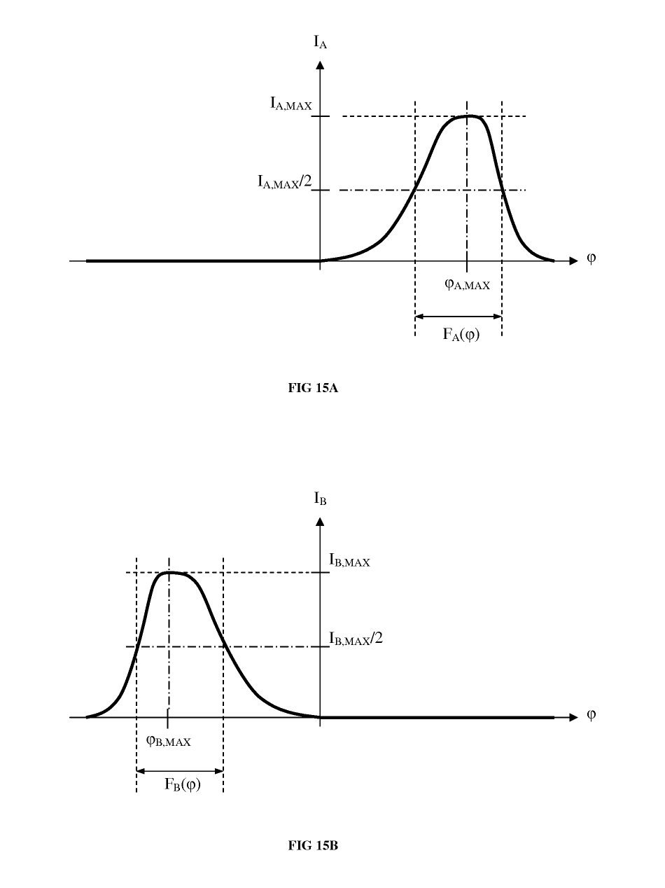

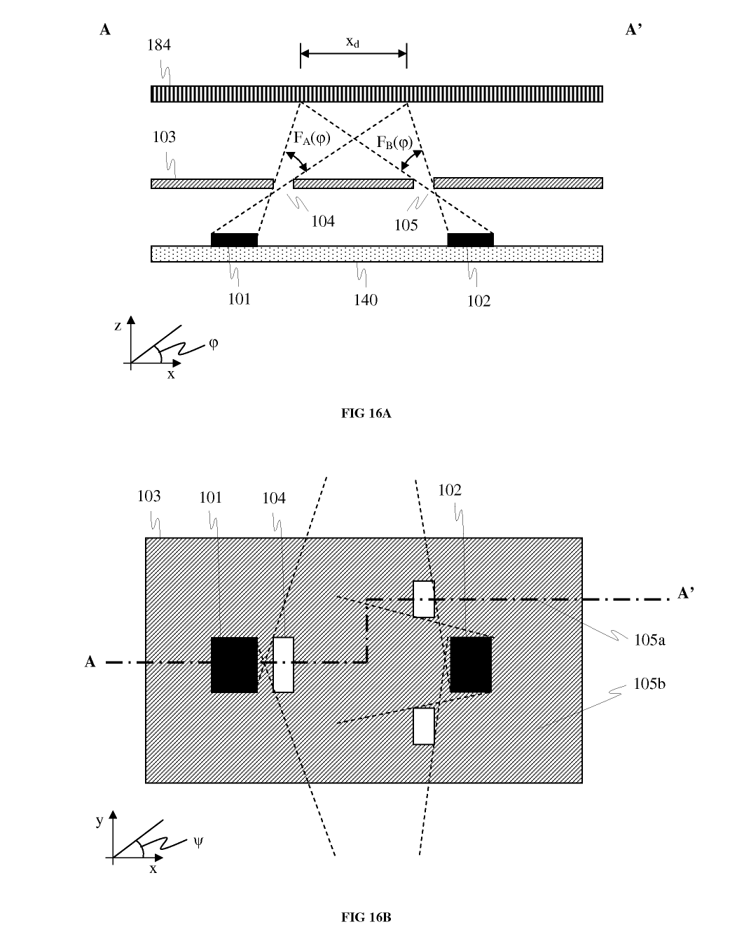

As an alternative, a third embodiment in accordance with the invention aims to solve the problem of spatial separation of the photosensitive elements with an arrangement wherein the one dimensional field-of-view in elevation of the first photosensitive element 101 is equal to the one dimensional field-of-view in elevation of the second photosensitive element 102 but aligned in the opposite direction. This desired fields-of-view for the photosensitive elements are shown in FIG. 15A and FIG. 15B for the first and second photosensitive element respectively. The geometry and arrangement of the apertures and photosensitive elements to achieve this desired field-of-view are shown in cross-section in FIG. 16A and in plan in FIG. 16B. As illustrated in the cross-section of FIG. 16A, if the distance between the document 184 placed on the display surface and the light blocking layer 103 is known, the first and second aperture may be arranged relative to the first and second photosensitive elements such that their fields-of-view in elevation overlap in the x-axis direction at the surface of the document in contact with the display. Since light is now reflected from the same x-location of the document, x_{d}, to both the first photosensitive element 101 and the second photosensitive element 102, the subtraction error due to the spatial separation of the two photosensitive elements is advantageously reduced.

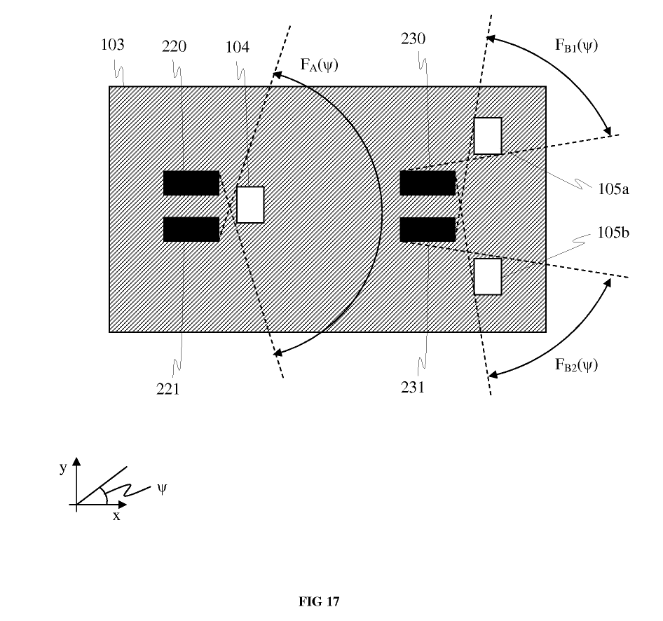

In a fourth embodiment in accordance with the invention, the first photosensitive element 101 and second photosensitive element 102 may be formed by a plurality of separate photosensitive sub-elements arranged in parallel. For example, as shown in FIG. 17, the first photosensitive element 101 may be formed by a first sub-element 220 and a second sub-element 221 and the second photosensitive element may be formed by a third sub-element 230 and a fourth sub-element 231. The first and second sub-elements and the third and fourth sub-elements are electrically connected so as to operate in parallel. The first aperture 104 and second aperture 105 are arranged in relation to the first and second photosensitive elements as described above in order to form the field-of-view for the sensor. An advantage of the sub-element arrangement of this embodiment is that the resulting sensor field-of-view may be made narrower than could otherwise be achieved in the arrangements of the previously described embodiments.

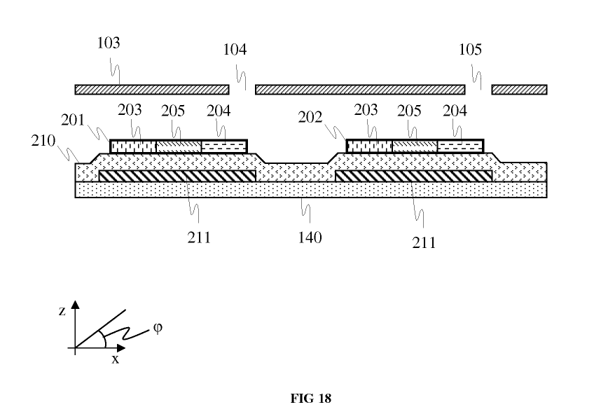

In an fifth embodiment in accordance with the invention, the photosensitive elements of the previous embodiments are formed by thin-film lateral photodiodes which include an additional electrode formed by a second light blocking layer 211 and disposed beneath the silicon layer forming the photodiode—as shown in FIG. 18. Although the sensor pixel circuit is arranged to output the difference between the photocurrent generated by the first and second photodiode, in practise this difference in photocurrent may arise due undesirable mismatch between the photodiode characteristics—introduced by the fabrication process—as well as the difference in the incident illumination. In order to reduce output offset errors due to this mismatch it is therefore desirable to reduce any sources of illumination common to both photodiodes that do not directly contribute to the sensor output signal. An advantage of this embodiment is therefore that the additional electrode, if formed by an opaque material, functions to prevent illumination from the display backlight from falling on the photodiodes and hence reduces errors in the output image due to photodiode mismatch.

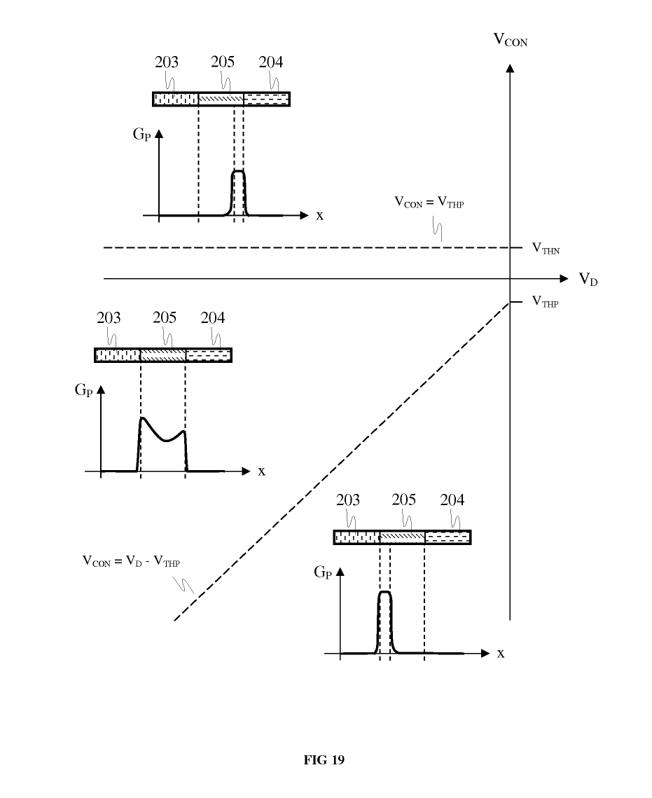

In a sixth embodiment of this invention, the electrode formed by the second light blocking layer 211 is used as a control electrode to further improve the sensor field-of-view. As is now described, the voltage applied to the control electrode V_{CON} of a thin-film lateral type photodiode may be varied in order to control the photo-generation profile of the photodiode and hence control the field-of-view of the image sensor. The relationship between the control voltage V_{CON}, the voltage between the diode anode and cathode terminals, V_{D}, and the photo-generation profile is shown in the graph of FIG. 19. In this graph, the photodiode cathode terminal is assumed to be at a fixed potential, such as the ground potential, to which all other voltages are referenced. As can be seen, the photodiode can be made to operate in one of three modes depending on the value of the control voltage, V_{CON}, in relation to the diode voltage, V_{D}. In a first mode of operation, the value of the control voltage V_{CON} is higher than a first threshold voltage of the photodiode, V_{THN}. In this first mode the photodiode intrinsic region is thus characterised by a high density of electrons towards the junction between the intrinsic region and the cathode and by a region substantially depleted of carriers at the junction between the intrinsic region and the anode. Since photo-generation occurs only in the depletion region, the photo-generation profile is therefore high at the junction between the intrinsic region and the anode and negligible elsewhere. In a second mode of operation, the value of the control voltage V_{CON} is lower than the diode voltage V_{D} minus a second threshold voltage of the photodiode V_{THP}. In this second mode the photodiode intrinsic region is thus characterised by a high density of holes towards the junction between the intrinsic region and the anode and by a region which is substantially depleted of carriers at the junction between the intrinsic region and the cathode. The photo-generation profile is therefore high at the junction between the intrinsic region and the cathode and negligible elsewhere. In a third mode of operation, the value of the control voltage V_{CON} is between the two limits defined in the first and second mode of operation. In this mode, the intrinsic region is substantially depleted of carriers through its entire volume and the photo-generation occurs across the whole region. The photo-generation profile is therefore of a similar shape to that of a thin-film lateral type photodiode with no control electrode as described previously and shown in FIG. 13.

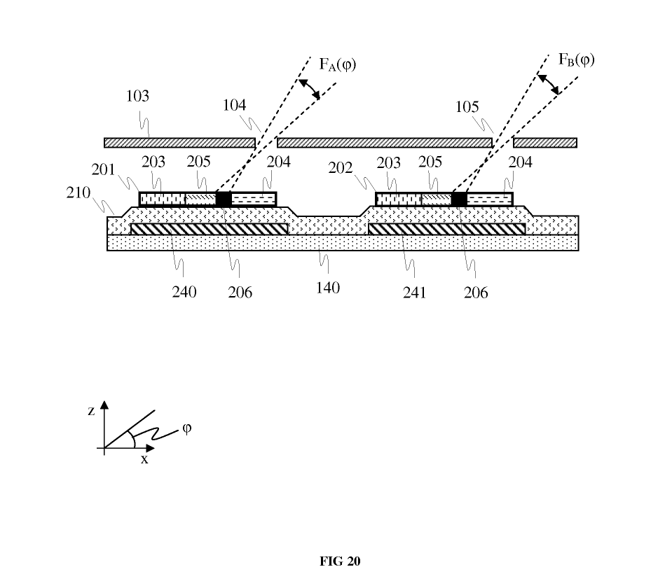

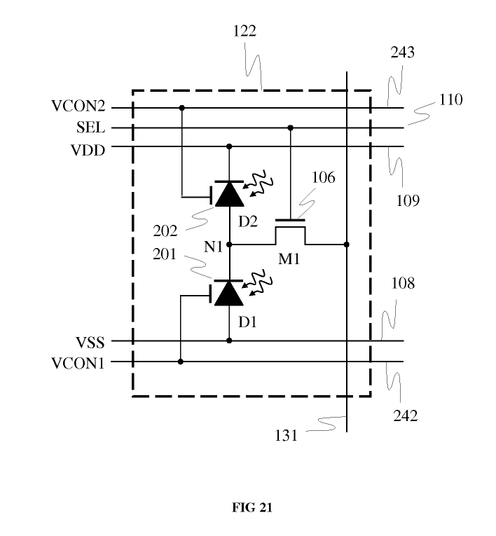

An example of how this method of controlling the photo-generation profile through the control electrode voltage can be used to narrow the sensor field-of-view in elevation is shown in FIG. 20. Here, a first control electrode 240 is formed in the second light blocking layer beneath the first photodiode 201 and a second control electrode 241 is formed in the second light blocking layer beneath the second photodiode 202. If the voltage of the first control electrode 240, V_{CON1}, is chosen to be greater than the first threshold voltage, V_{CON1}>V_{THN}, then the first photodiode will be placed in the first mode of operation. If the voltage of the second control electrode 240, V_{CON2}, is chosen to be greater than the first threshold voltage V_{CON2}>V_{THN}, then the second photodiode will also be placed in the first mode of operation. Accordingly, the depletion regions 206 of the first and second photodiodes will be located towards the anode terminal and will be significantly shorter than the length of the intrinsic region 205. The field-of-view in elevation of each photodiode is therefore made narrower than in the previous embodiments since the range of angles of incident light that cause photo-generation in the photodiodes is reduced. From the preceding description it should be obvious that an alternative arrangement to create a narrow field-of-view by this method exists wherein the apertures are arranged adjacent to the cathode terminal of the photodiodes and the first and second control electrode are supplied with voltages to place the first and second photodiodes into the second mode of operation.

FIG. 20 shows a schematic diagram of the pixel circuit of this sixth embodiment. The circuit is similar to that described in the second embodiment of this invention and shown in FIG. 14 but also includes a first control electrode address line 242 (VCON1) to supply the voltage to the first control electrode 240 and a second control electrode address line 243 (VCON2) to supply the voltage to the second control electrode 241. The operation of this pixel circuit is as described previously.

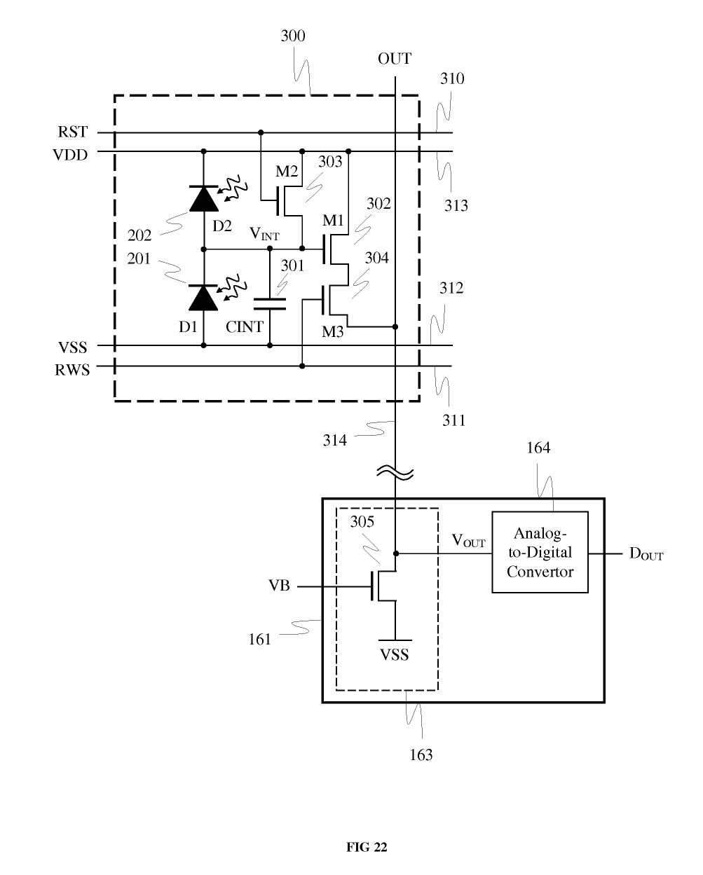

In a seventh embodiment in accordance with the invention, the image sensor circuit elements 100 are formed by an active pixel sensor circuit 300 wherein an amplifier transistor is used to amplify the signal generated by the photosensitive elements and thereby improve the performance of the image sensor system. The active pixel circuit may be of a known construction, for example as disclosed in WO2010/097984 (Katoh et al., Feb. 27, 2009) and shown in FIG. 22. The active pixel sensor circuit may comprise: a first photodiode (PD1) 201; a second photodiode (PD2) 202; an integration capacitor (CINT) 301; an amplifier transistor, (M1) 302; a reset transistor (M2) 303; a row select transistor (M3) 304; a reset input signal address line (RST) 310; a row select input signal address line (RWS) 311; a low power supply line (VSS) 312; and a high power supply line (VDD) 313. The output terminal of the row select transistor 304 may be connected to the output signal line (OUT) 314. As described in previous embodiments, the first photodiode 201 is arranged in co-operation with a first aperture 104 formed in the light blocking layer 103 and the second photodiode 202 is arranged in co-operation with a second aperture 105 formed in the light blocking layer 103.

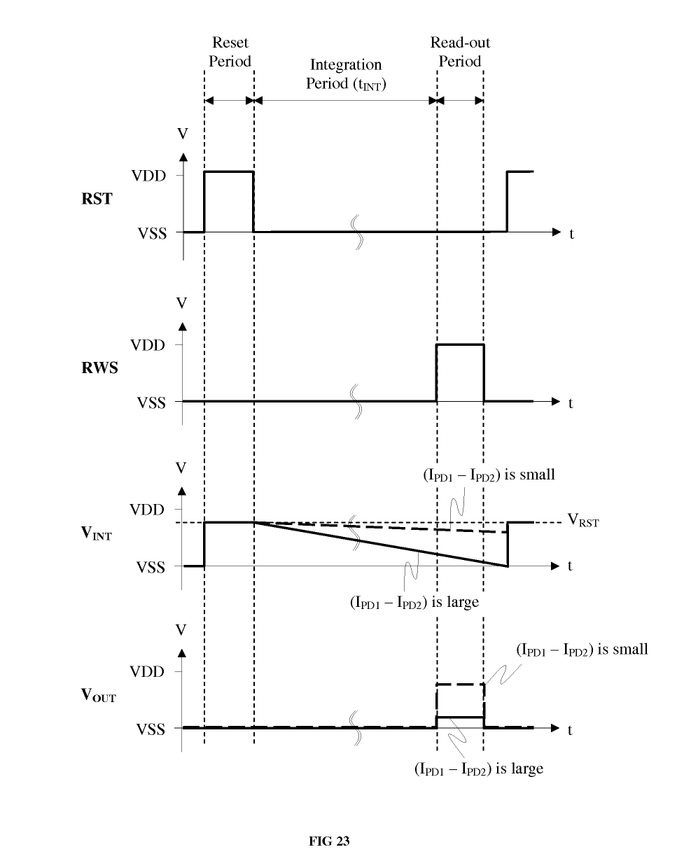

The operation of this pixel circuit occurs in three stages, or periods as is now described with reference to the waveform diagram of FIG. 23. At the start of a first reset period the reset input signal RST is made high and the reset transistor is turned on. During this period, the voltage at the gate terminal of the amplifier transistor M1, known as the integration node, is therefore reset to an initial reset voltage, V_{RST}, which may be equal to the voltage of the high power supply line (VDD) 313. The reset input signal RST is now made low causing the reset transistor M2 to turn off and the integration period begins. During the integration period, the difference between the currents flowing in the first and second photodiodes is integrated on the integration capacitor (CINT) 301 causing the integration node to drop from its reset level. The rate of decrease in the voltage of the integration node is proportional to the difference in incident illumination between the first and second photodiodes. At the end of the integration period, the voltage of the integration node, V_{INT}, is given by:

V_{INT}=V_{RST}−((I_{PD1}−I_{PD2})·t_{INT})/C_{INT}

where V_{RST} is the reset potential of the integration node; I_{PD1} and I_{PD1} are the currents flowing in the first and second photodiodes respectively; t_{INT} is the integration period; and C_{INT} is the capacitance of the integration capacitor CINT.

At the end of the integration period the pixel is sampled during a read-out period. In this period the row select input signal RWS is made high and the read-out transistor is turned on connecting the amplifier transistor to a bias transistor (M4) 305 located at the end of the output signal line (OUT) 314. The bias transistor 305 is supplied with a constant bias voltage VB and constitutes a pixel sampling circuit 163 by forming a source follower amplifier circuit with the pixel amplifier transistor 302. During the read-out period the source follower amplifier generates an output voltage, V_{OUT}, which is proportional to the integration node voltage and hence to the difference between the illumination incident on the first and second photodiodes. As before, the pixel output voltage may then be converted to a digital value by an analog-to-digital convertor circuit 164 within the read-out circuits 161. At the end of the read-out period, the row select signal RWS is made low and the read-out transistor M3 is turned off. The pixel may now be reset and the three-stage operation of the pixel circuit repeated indefinitely. The above description is intended to provide an example of the use of an active pixel sensor circuit with the current invention. Any well-known type of active pixel sensor circuit—such as a one transistor type active pixel sensor circuit as disclosed, for example, in US 20100231562 (Brown, Sep. 16, 2010)—and associated pixel sampling circuit may be used instead.

An advantage of the active pixel sensor circuit compared with the passive pixel sensor circuit described in the previous embodiments is that the system is less susceptible to noise and other sources of interference. The quality of the image obtained with an active pixel sensor is therefore higher and the size of the array may also be increased.

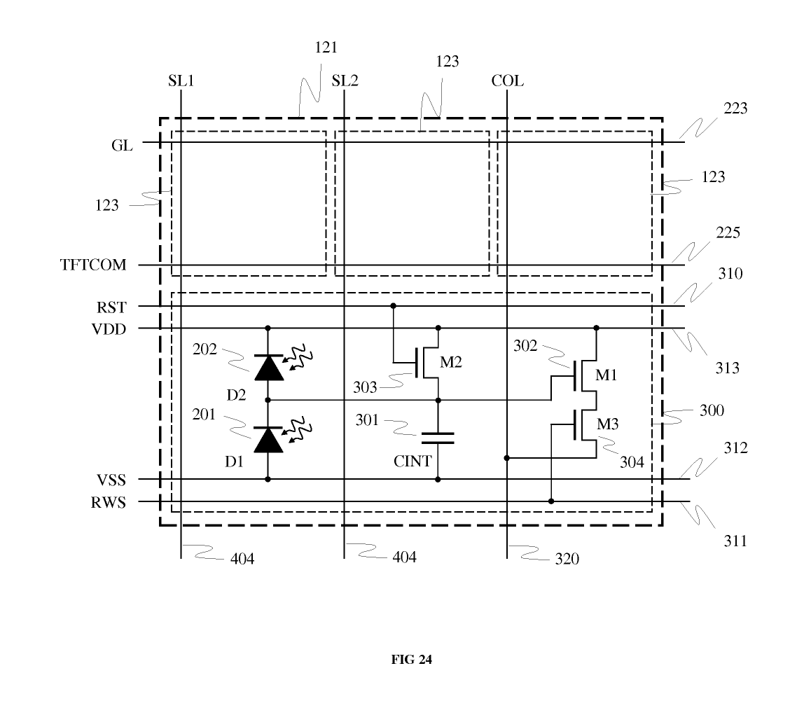

In an eighth embodiment in accordance with the invention, the combined display and sensor pixel circuit 121 may be formed by distribution of the image sensor circuit elements 100 across a plurality of display pixel circuits 123. For example, as illustrated in FIG. 24, the active pixel circuit 300 of the previous embodiment may be distributed across three display pixel circuits. The image sensor circuit elements may be distributed across the plurality of pixel circuits in any suitable arrangement. However, it is advantageous to locate the first and second photodiodes adjacent to each other in order to minimize the subtraction error as described previously. Further, one of the display source address lines and the sensor output signal line may be combined such that one column address line (COL) 320 is used to perform both functions. In this case, access to the column address line by the sensor and display functions is by time-sharing. For example, it is well-known that in such a system the sensor read-out period may be arranged to coincide with the display horizontal blanking period. An advantage of this arrangement is that the area occupied by the image sensor circuit elements 100 in the matrix may be reduced and the aperture ratio of the display pixel circuit 123 increased. As a consequence, the brightness of the display may be increased or the power consumption of the display backlight may be reduced to achieve a similar brightness.

Although the invention has been shown and described with respect to a certain embodiment or embodiments, equivalent alterations and modifications may occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein exemplary embodiment or embodiments of the invention. In addition, while a particular feature of the invention may have been described above with respect to only one or more of several embodiments, such feature may be combined with one or more other features of the other embodiments, as may be desired and advantageous for any given or particular application.

### INDUSTRIAL APPLICABILITY

The LCD device with integrated image sensor in accordance with the present invention may be used to create a display with an in-built touch panel function. Alternatively, the LCD device may form a contact scanner capable of capturing an image of any object or document placed on the surface of the display. Accordingly, the invention has industrial applicability.

1. An image sensor, comprising an array of sensor pixel circuits, each pixel circuit comprising first and second photosensitive elements, wherein a field of view of the second photosensitive element is a sub-set of a field of view of the first photosensitive element.

2. The image sensor according to claim 1, further comprising a circuit configured to measure a difference in signals generated by the first and second photosensitive elements so as to create an effective field-of-view for the image sensor that is the difference between the fields-of-view of the first and second photosensitive elements.

3. The image sensor according to claim 1, comprising;
a light-blocking layer arranged relative to the first and second photosensitive elements; and
a first and a second aperture formed in the light-blocking layer, the first aperture corresponding to the first photosensitive element and the second aperture corresponding to the second photosensitive element, the first and second apertures arranged relative to the first and second photosensitive elements, respectively, to create substantially the same field of view in each photosensitive element in a first angular dimension, and different fields-of-view in a second angular dimension.

4. The image sensor according to claim 3, wherein a location of the first aperture is characterized in an x-direction by an offset between an edge of the first photosensitive element adjacent to the first aperture and a width of the first aperture, and characterized in the y-direction by a length of the first aperture being substantially the same as a length of the photosensitive element in the y-direction.

5. The image sensor according to claim 4, wherein a location of the second aperture is characterized in the x-direction by an offset between an edge of the second photosensitive element adjacent to the second aperture and width of the second aperture, and characteristics of the second aperture in the x-direction are substantially the same as the characteristics of the first aperture in the x-direction.

6. The image sensor according to claim 4, wherein the second aperture is split into two sub-apertures formed on either side of the second photosensitive element, and each sub-aperture is characterized in the y-direction by an offset from the edge of the second photosensitive element adjacent to the sub-apertures and a length of the sub-apertures.

7. The image sensor according to claim 6, wherein the length and offset of the sub-apertures in the y-direction are chosen such that two distinct fields-of-view in the second angular dimension are created, each distinct field-of-view being a sub-set of the field-of-view of a one dimensional field-of-view in azimuth created by the first aperture.

8. The image sensor according to claim 1, wherein the first and second photosensitive elements comprise thin-film lateral p-i-n type photodiodes.

9. The image sensor according to claim 3, further comprising an imaging surface for placing an object to be imaged, wherein the first and second apertures are arranged relative to the first and second photosensitive elements, respectively, such that fields-of-view in elevation for the first and second photosensitive elements overlap in the x-axis direction at the imaging surface.

10. The image sensor according to claim 1, wherein the first photosensitive element and the second photosensitive element are formed by a plurality of separate photosensitive sub-elements arranged in parallel.

11. The image sensor according to claim 3, further comprising a second light blocking layer, wherein the first and second photosensitive elements comprise a thin-film lateral photodiode including a control electrode formed by the second light blocking layer.

12. The image sensor according to claim 11, wherein the thin-film photodiodes comprise a silicon layer, and the second light blocking layer is disposed beneath the silicon layer.

13. The image sensor according to claim 11, wherein the control electrode of the first and second photodiodes is configured to control a photo-generation profile of the respective photodiode.

14. The image sensor according to claim 11, wherein the first and second apertures are arranged adjacent to a cathode terminal of the first and second photodiodes, respectively.

15. The image sensor according to claim 2, further comprising a first control electrode address line configured to supply voltage to the control electrode of the first photosensitive element, and a second control electrode address line configured to supply voltage to the control electrode of the second photosensitive element.

16. The image sensor according to claim 1, wherein image sensor circuit elements are formed by an active pixel sensor circuit.

17. The image sensor according to claim 16, wherein the active pixel sensor circuit includes an amplifier configured to amplify a signal generated by the photosensitive elements.

18. The image sensor according to claim 1, further comprising a display pixel circuit, wherein the image sensor is integrated together with the display pixel circuit to from a combined pixel circuit configured to perform both output display and input sensor functions.

19. The image sensor according to claim 18, wherein the combined display and sensor pixel circuit is formed by distribution of image sensor circuit elements across a plurality of display pixel circuits.

20. The image sensor according to claim 1, wherein the first and second photosensitive elements are electrically connected to each other to form a summing node, further comprising a switching device electrically coupled to the summing node.

21. A contact scanner, comprising the image sensor according to claim 1.

22. A touch panel, comprising the image sensor according to claim 1.

23. A method of generating a narrow-field of view for an image sensor integrated with an LCD device, said image sensor including first and second photosensitive elements, comprising:
configuring a field of view of the second photosensitive element to be a sub-set of a field of view of the first photosensitive element;
generating an effective field of view for the image sensor from a difference between a signal generated by the first photosensitive element and a signal generated by the second photosensitive element.

24. The method according to claim 23, wherein configuring includes providing the first and second photosensitive elements with substantially the same field of view in a first angular dimension, and different fields-of-view in a second angular dimension.
